(19) United States
(12) Patent Application Publication
(10) Pub. No.: US 2015/0140728 A1
(43) Pub. Date: May 21, 2015

(54) METHOD FOR AVOIDING SHORT CIRCUIT OF METAL CIRCUITS IN OLED DISPLAY DEVICE

(71) Applicant: SHENZHEN CHINA STAR OPTOELECTRONICS TECHNOLOGY CO., LTD., Shenzhen, Guangdong (CN)

(72) Inventor: Kai-Yuan Ko, Shenzhen (CN)

(73) Assignee: SHENZHEN CHINA STAR OPTOELECTRONICS TECHNOLOGY CO., LTD., Shenzhen, Guangdong (CN)

(21) Appl. No.: 14/240,351

(22) PCT Filed: Jan. 23, 2014
(86) PCT No.: PCT/CN2014/071278

§ 371 Date: Feb. 21, 2014

(30) Foreign Application Priority Data
Oct. 12, 2013 (CN) 201310476928.2

(51) Int. Cl. H01L 27/32; H01L 51/56

(52) U.S. Cl. CPC H01L 27/3276; H01L 51/56; H01L 2227/323
USPC 438/99

(57) ABSTRACT

The present invention relates to a method for avoiding short circuit of metal circuit lines in an OLED display device, including the steps of: forming an inorganic layer on a substrate; forming a patterned metal layer on the inorganic layer, wherein the patterned metal layer includes more than two metal circuit lines; forming a patterned organic layer on the patterned metal layer, wherein the patterned organic layer is provided with an island area at its edge and between every two adjacent metal circuit lines, which has a height lower than that of other periphery areas of the patterned organic layer; forming an ITO layer on the patterned organic layer. In the present invention, an island area with lower height is formed at the edge of the organic layer, such that ITO deposited at the edge of the organic layer is partially deposited on the island area; and ITO on the island area can be completely etched and removed in the later photo etching process, such that ITO remained at the edge of the organic layer is no longer continuous between two adjacent metal circuit lines, thus avoiding short circuit of the two adjacent metal circuit lines due to the remained ITO.

### FIELD OF THE INVENTION

The present disclosure relates to manufacturing process for a semiconductor display panel, and particularly, to a method for avoiding short circuit of metal circuits in an OLED display device.

### BACKGROUND OF THE INVENTION

Indium tin oxide (ITO) film, due to its excellent electric conductivity and transmittance, good adhesion to a substrate, good stability and good etching property, is widely used for manufacturing transparent electrodes in high-tech products, such as, a semiconductor display panel. For example, the ITO film is prepared to be an anode in an OLED (Organic Light-Emitting Diode) display device. The manufacturing procedures of the OLED display device are roughly divided into two parts, i.e., manufacturing a plurality of thin-film transistors serving as switch elements onto a substrate and manufacturing organic light-emitting diodes serving as light-emitting elements onto the substrate. As shown in FIG. 1A, firstly, a gate layer (not shown) and a semiconductor layer (not shown) are formed on the substrate (not shown), next, an inorganic layer (not shown) is formed, then a metal layer 10 including more than two metal circuit lines M1 and M2 respectively for transmitting different signals is formed on the inorganic layer, and an organic layer 20 is formed on the metal layer 10, in the following, an ITO layer (not shown) serving as an anode of an organic light-emitting diode is formed on the organic layer 20, and finally, a light-emitting layer (not shown) and a corresponding cathode (not shown) are successively formed on the ITO layer.

As shown in FIG. 1B, in the above-mentioned manufacturing process, the edge of the organic layer 20 presents a shape of abrupt slope. When ITO is coated on the organic layer 20, ITO 30 may be deposited at the bottom of the abrupt slope. As the organic layer 20 is relatively high, exposure rays can not irradiate a photoresist at the bottom of the abrupt slope during the later photoetching process performed on ITO, thus causing poor development of the photoresist, such that ITO 30 deposited at the bottom of the abrupt slope cannot be etched off, and a strip of ITO 30 may be remained at the bottom of the slope at the edge of the organic layer after the manufacturing process is completed. When the strip of ITO 30 simultaneously contacts two adjacent metal circuit lines M1 and M2, short circuit may occur between the two metal circuit lines M1 and M2, causing abnormality of signals.

To solve the above-mentioned problems, a common approach in the prior art is to expose the photoresist on the organic layer 20 by using a photomask 40 having patterned apertures as shown in FIG. 2A, such that gradient of the abrupt slope at the edge of the organic layer 20 presents gradually reduced status (as shown in FIG. 2B), and thus the ITO remained at the edge of the organic layer can be conveniently removed later. However, in the practical manufacturing process, the approach cannot fully achieve the expected effect due to the limitation of process conditions, and it is costly in labor and time consumption. Therefore, researchers of the present disclosure propose a much easier method for avoiding short circuit of metal circuit lines in the OLED display device, which can avoid short circuit between the two adjacent metal circuit lines, due to remaining ITO, without removing all ITO remained at the edge of the organic layer.

### SUMMARY OF THE INVENTION

Aiming at the above-mentioned problems, the present disclosure proposes a much easier method for avoiding short circuit of metal circuit lines in an OLED display device, including the steps of:

forming an inorganic layer on a substrate;

forming a patterned metal layer on the inorganic layer, wherein the patterned metal layer includes more than two metal circuit lines;

forming a patterned organic layer on the patterned metal layer, wherein the patterned organic layer is provided with an island area at its edge and between every two adjacent metal circuit lines, height of which is lower than that of other periphery areas of the patterned organic layer;

forming an ITO layer on the patterned organic layer.

Further, the step of forming the patterned organic layer on the metal layer includes the steps of:

successively coating an organic layer and a photoresist layer on the substrate;

exposing the photoresist layer by a photomask, wherein patterned apertures of the photomask corresponding to the island area are larger than those of the photomask corresponding to etching-free regions and smaller than those of the photomask corresponding to full-etching regions;

developing the photoresist layer; and

removing a part of the organic layer by etching.

According to an embodiment of the present disclosure, the size of the patterned apertures of the photomask corresponding to the island area is 2 micrometers, the size of the patterned apertures of the photomask corresponding to the etching-free regions is 0 to 2 micrometers, and the size of the patterned apertures of the photomask corresponding to the full-etching regions is more than 2.5 micrometers.

According to an embodiment of the present disclosure, the patterned organic layer may be provided with two island areas between the two metal circuit lines.

Further, the above-mentioned organic layer at least covers portions of the two metal circuit lines.

In addition, the above-mentioned two metal circuit lines are used for transmitting different signals respectively.

Further, the above-mentioned two metal circuit lines are used for transmitting different source signals respectively.

Further, the above-mentioned two metal circuit lines are used for transmitting different drain signals respectively.

Compared with the prior art, the present disclosure has the advantages that an island area with lower height is formed at the edge of the organic layer, such that ITO deposited at the edge of the organic layer is partially deposited on the island area; and ITO on the island area can be completely etched and removed in the later photoetching process, such that ITO remained at the edge of the organic layer is no longer continuous between two adjacent metal circuit lines, thus avoiding short circuit of the two adjacent metal circuit lines.

### BRIEF DESCRIPTION OF THE DRAWINGS

The accompanying drawings are provided for further understanding the present disclosure, and constitute a part of the description for interpreting the present disclosure together with the examples of the present disclosure, rather than limit to the present disclosure, wherein:

FIG. 1A is a top view of the layout of partial elements of an OLED display device in the prior art;

FIG. 1B is a section view of FIG. 1A along a line segment A-A′;

FIG. 2A is a local schematic diagram of an organic layer photomask capable of removing ITO remained at the edge of an organic layer in the prior art;

FIG. 2B is a section view along a line segment B-B′ after photoetching of the organic layer of FIG. 2A;

FIG. 3 is a flow diagram of a method of the present disclosure;

FIG. 4A is a top view of arrangement of an island area of the organic layer according to one example of the present disclosure;

FIG. 4B is a section view along a line segment C-C′ after photoetching of the organic layer of FIG. 4A;

FIG. 5A is a top view of arrangement of an island area of the organic layer according to another example of the present disclosure;

FIG. 5B is a section view along a line segment D-D′ after photoetching of the organic layer of FIG. 5A.

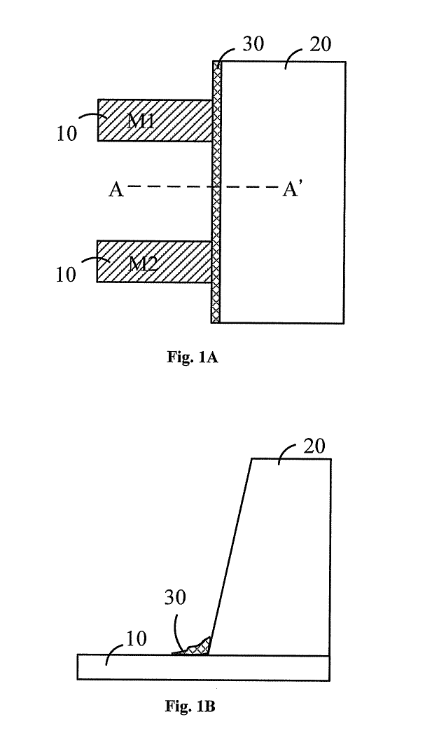

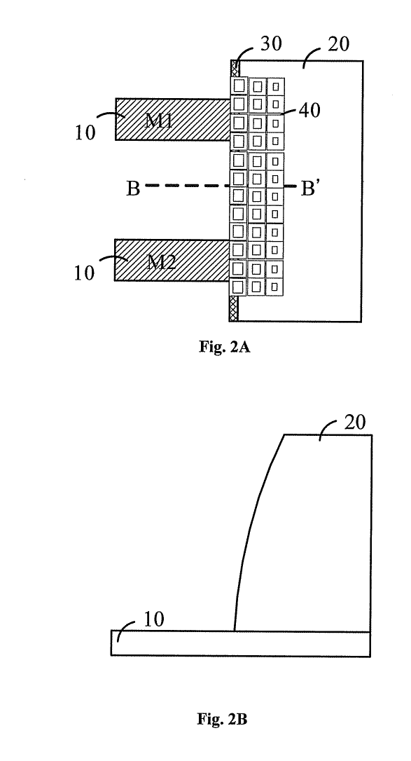

### DETAILED DESCRIPTION OF THE EMBODIMENTS

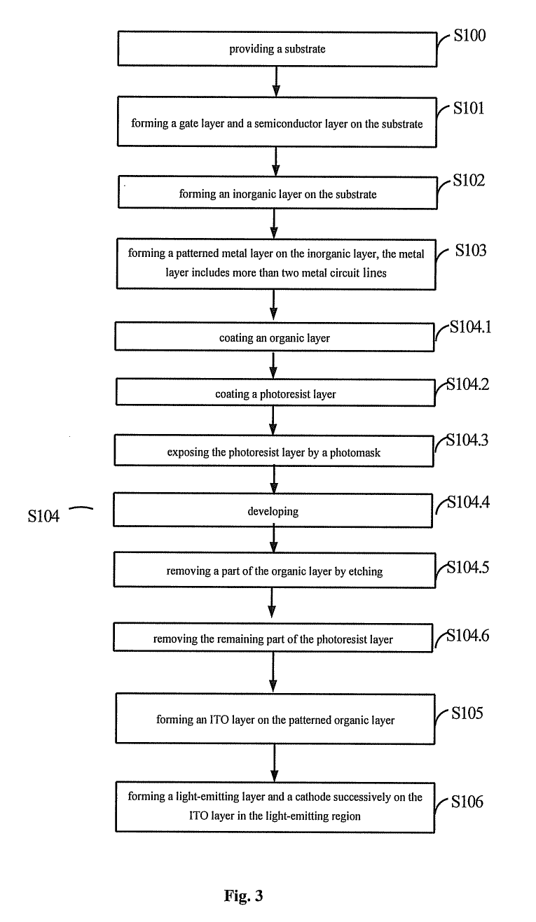

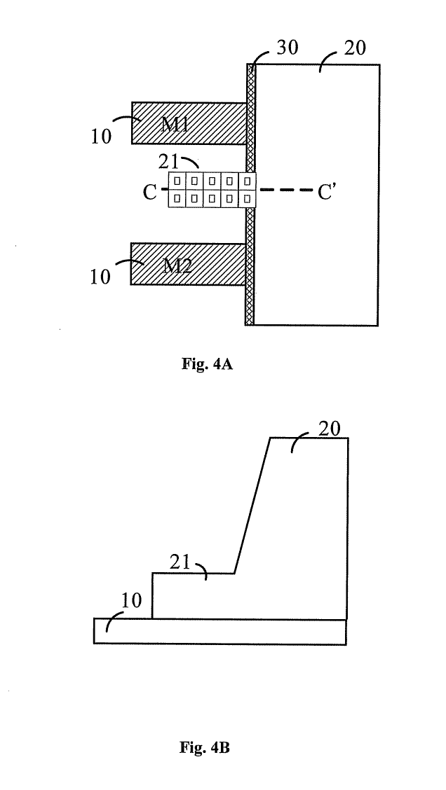

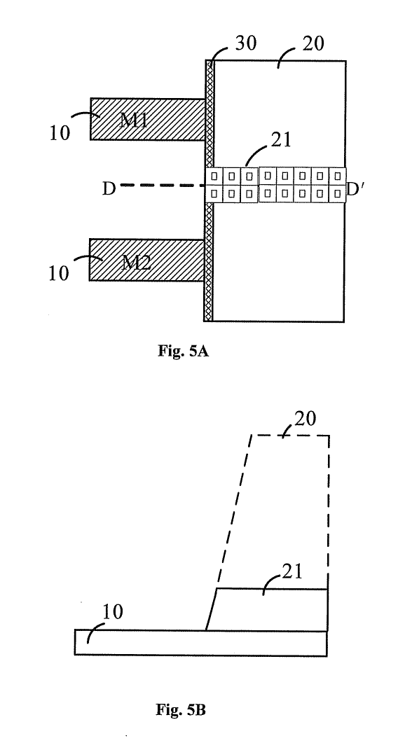

FIG. 3 shows a flow diagram of a method proposed in the present disclosure for avoiding short circuit of metal circuit lines in an OLED display device. To further illustrate the objectives, technical solutions and achieved technical effects of the present disclosure, the present disclosure will be discussed in detail below in conjunction with non-limiting examples. FIG. 4A, FIG. 4B, FIG. 5A and FIG. 5B. As to the referred directional terms, such as, up, down, front, back, left, right, inner, outer and lateral sides etc., reference is merely made to the directions of accompanying drawings. Accordingly, the adopted directional terminology is merely used for illustrating and understanding rather than limit to the present disclosure.

Step S100, a substrate is provided.

Step S102, a gate layer and a semiconductor layer are formed on the substrate.

Step S103, an inorganic layer is formed on the substrate.

It should be noted that an region on the substrate formed by the inorganic layer is different from regions on the substrate formed by the gate layer and the semiconductor layer. Moreover, since the forming manners of the gate layer, the semiconductor layer and the inorganic layer are same as those in the prior art and are not the key points of the present disclosure, they are thereby not shown in the figures or described in detail.

Step S104, a patterned metal layer 10 is formed on the inorganic layer, wherein the patterned metal layer 10 includes more than two metal circuit lines. In this example, only two metal circuit lines M1 and M2 are taken as an example for illustration, but the number of the metal circuit lines is actually not limited to so. The metal circuit lines M1 and M2 are used for transmitting different signals respectively, for example, transmitting different source signals or drain signals.

Step S105, a patterned organic layer 20 is formed on the patterned metal layer 10, wherein the patterned organic layer 20 is provided with an island area 21 at its edge and between every two adjacent metal circuit lines, height of which is lower than that of the periphery patterned organic layer 20.

FIG. 4A shows a top view of arrangement of an island area of the organic layer according to one example of the present disclosure. The organic layer 20 at least covers portions of the two metal circuit lines M1 and M2, and extends outwards at its edge to form one island area 21 between the two metal circuit lines M1 and M2, and height of the organic layer 20 at the island area 21 is lower than that of the organic layer 20 at other periphery areas, such that a ladder-like structure with a cross section shown in FIG. 4B is formed between the two metal circuit lines M1 and M2 and at the edge of the organic layer 20. As it should be, a plurality of such island areas may also be formed between two adjacent metal circuit lines, which is not limited in the present disclosure.

Alternatively, FIG. 5A shows a top view of arrangement of an island area of the organic layer according to another example of the present disclosure. The organic layer 20 at least covers portions of the two metal circuit lines M1 and M2, and between the two metal circuit lines M1 and M2, the organic layer 20 does not extend outwards at its edge but is provided with a depressed area 21, where height of the organic layer 20 is lower than that of the organic layer 20 at other periphery areas. Thereby, the depressed area 21 is also referred to as island area 21, and the cross section thereof is as shown in FIG. 5B. As it should be, a plurality of such island areas may also be formed between two adjacent metal circuit lines, which is not limited in the present disclosure.

The method for manufacturing the organic layer 20 with the above-mentioned island area 21 includes the steps of:

Step S105.1, coating an organic layer on the substrate;

Step S105.2, coating a photoresist layer on the substrate;

Step S105.3, exposing the photoresist layer via a photomask, wherein patterned apertures of the photomask corresponding to the island area are larger than those of the photomask corresponding to etching-free regions and smaller than those of the photomask corresponding to full-etching regions;

Step S105.4, developing the photoresist layer;

Step S105.5, removing a part of the organic layer by etching.

In the above-mentioned S105.3, as the patterned apertures of the photomask corresponding to the island area are larger than those of the photomask corresponding to etching-free regions, the photoresist at the island area 21 can not be completely exposed during the exposure process, such that the organic layer 20 at the island area 21 is lower than the organic layer 20 at other periphery areas after developing and etching.

Taking an exposure machine of Canon Inc as an example, the resolution of the exposure machine is 2.5 micrometers (μm). Accordingly, the size of the patterned apertures of the photomask corresponding to the island area may be preferably 2 microns, and correspondingly, the size of the patterned apertures of the photomask corresponding to the etching-free regions is smaller than 2 micrometers, and the size of the patterned apertures of the photomask corresponding to the full-etching regions is more than 2.5 micrometers.

Step S106, a patterned ITO layer is formed on the patterned organic layer.

Since the preparation process used in this step is a conventional technique, it is no longer described in detail herein.

In S106, when the ITO layer is coated, ITO 30 deposited at the edge of the organic layer 20 may be partially deposited on the island area 21; at the exposure stage, the photoresist of ITO on the island area can be completely exposed; and after developing and etching, ITO on the island area can be completely removed, such that ITO remained at the edge of the organic layer is no longer continuous between the two adjacent metal circuit lines, thus avoiding short circuit of the two adjacent metal circuit lines due to ITO remained at the edge of the organic layer.

In conclusion, there is no strict limit to size, location and number of the island area 21 of the organic layer 20 in the present disclosure, as long as ITO remained at the edge of the organic layer is no longer continuous between the two adjacent metal circuit lines.

Although the present disclosure has been described with reference to the preferred examples, various modifications may be made to the present disclosure and components therein could be substituted by equivalents without departing from the scope of the present disclosure. The present disclosure is not limited to the specific examples disclosed in the description, but includes all technical solutions falling into the scope of the claims.

What is claimed is:

1. A method for avoiding short circuit of metal circuit lines in an OLED display device, including the steps of:
forming an inorganic layer on a substrate;
forming a patterned metal layer on the inorganic layer, wherein the patterned metal layer includes more than two metal circuit lines;
forming a patterned organic layer on the patterned metal layer, wherein the patterned organic layer is provided with an island area at its edge and between every two adjacent metal circuit lines, which has a height lower than that of other periphery areas of the patterned organic layer; and
forming an ITO layer on the patterned organic layer.

2. The method of claim 1, wherein, the step of forming the patterned organic layer on the metal layer includes the steps of:
successively coating an organic layer and a photoresist layer on the substrate;
exposing the photoresist layer by a photomask, wherein patterned apertures of the photomask corresponding to the island area are larger than those of the photomask corresponding to etching-free regions and smaller than those of the photomask corresponding to full-etching regions;
developing and etching the photoresist layer to remove a part of the organic layer.

3. The method of claim 2, wherein, the size of the patterned apertures of the photomask corresponding to the island area is 2 micrometers, the size of the patterned apertures of the photomask corresponding to the etching-free regions is 0 to 2 micrometers, and the size of the patterned apertures of the photomask corresponding to the full-etching regions is more than 2.5 micrometers.

4. The method of claim 1, wherein,
edge of the patterned organic layer is provided with two island areas between the two metal circuit lines.

5. The method of claim 2, wherein,
edge of the patterned organic layer is provided with two island areas between the two metal circuit lines.

6. The method of claim 1, wherein,
the organic layer at least covers portions of the two metal circuit lines.

7. The method of claim 2, wherein,
the organic layer at least covers portions of the two metal circuit lines.

8. The method of claim 4, wherein,
the organic layer at least covers portions of the two metal circuit lines.

9. The method of claim 5, wherein,
the organic layer at least covers portions of the two metal circuit lines.

10. The method of claim 1, wherein,
the two metal circuit lines are used for transmitting different signals respectively.

11. The method of claim 2, wherein,
the two metal circuit lines are used for transmitting different signals respectively.

12. The method of claim 4, wherein,
the two metal circuit lines are used for transmitting different signals respectively.

13. The method of claim 5, wherein,
the two metal circuit lines are used for transmitting different signals respectively.

14. The method of claim 6, wherein,
the two metal circuit lines are used for transmitting different signals respectively.

15. The method of claim 7, wherein,
the two metal circuit lines are used for transmitting different signals respectively.

16. The method of claim 8, wherein,
the two metal circuit lines are used for transmitting different signals respectively.

17. The method of claim 9, wherein,
the two metal circuit lines are used for transmitting different signals respectively.

18. The method of claim 10, wherein,
the two metal circuit lines are used for transmitting different source signals respectively.

19. The method of claim 10, wherein,
the two metal circuit lines are used for transmitting different drain signals respectively.
